(19) United States
(12) Patent Application Publication
(10) Pub. No.: US 2018/0006043 A1
(43) Pub. Date: Jan. 4, 2018

(54) PREPARATION METHOD FOR FLAT CELL ROM DEVICE

(71) Applicant: CSMC TECHNOLOGIES CO., LTD, Wuxi New District, Jiangsu (CN)

(72) Inventors: Guipeng SUN, Wuxi New District (CN); Qiong WANG, Wuxi New District (CN); Guangtao HAN, Wuxi New District (CN)

(73) Assignee: CSMC TECHNOLOGIES FAB2 CO., LTD, Wuxi New District (CN)

(21) Appl. No.: 15/547,278

(22) PCT Filed: Sep. 23, 2015
(86) PCT No.: PCT/CN2015/090375

§ 371 Date: Jul. 28, 2017

(30) Foreign Application Priority Data
Jan. 29, 2015 (CN) 201510048123.7

(51) Int. Cl. H01L 27/112; H01L 21/265; H01L 21/266; H01L 29/06

(52) U.S. Cl. CPC H01L 27/11266; H01L 29/0607; H01L 21/26513; H01L 21/26586; H01L 21/266

(57) ABSTRACT

A preparation method for a flat cell ROM device, comprising the steps of: providing a substrate, and forming a P well on the substrate; forming a photomask layer on the P well and performing photoetching to form an injection window; injecting P-type ions in the formed injection window to form a P-type region; injecting N-type ions in the injection window so as to form an N-type region on the P-type region; and forming a gate oxide layer and a poly-silicon gate so as to complete the preparation of a device.

### FIELD OF THE INVENTION

The present disclosure relates to a field of semiconductor manufactures, and more particularly relates to a method of manufacturing a flat cell read-only memory (ROM) device.

### BACKGROUND OF THE INVENTION

In integrated circuits such as a micro control unit (MCU), an application specific integrated circuit (ASIC), and so on, a large area of the flat cell ROM arrays are usually required to store and read various programs and data. In order to improve the reliability of the flat cell ROM circuit, it is necessary to increase a withstand voltage of a device, and to reduce a leakage current and to alleviate a punch through phenomenon. In a conventional manufacturing process, after the fabrication of an N-type region (N-type region serves as a source-drain region of the flat cell ROM device), an additional isolation mask is usually added to perform dopant ion implantation to prevent an occurrence of the punch through phenomenon between a source and a drain, which increases a process cost and difficulty.

### SUMMARY OF THE INVENTION

Accordingly, it is necessary to provide a method of manufacturing a flat cell ROM device, which can effectively reduce a process cost and a leakage current of a source-drain, and improve a breakdown voltage (BV) of the device.

A method of manufacturing a flat cell ROM device includes the following steps of:

providing a substrate;

forming a P well on the substrate;

forming a photolithography mask layer on the P well and performing photolithography to form an implantation window;

performing P-type ion implantation to the implantation window by using the photolithography mask layer to form a P-type region;

performing N-type ion implantation to the implantation window by using the photolithography mask layer to form an N-type region on the P-type region; wherein the N-type region comprises a first N-type region and a second N-type region; the first N-type region and the second N-type region serve as a source and a drain of the flat cell ROM device, respectively;

forming a gate oxide layer on surfaces of the substrate and the N-type region; and

forming a polysilicon gate on a surface of the gate oxide layer.

According to the aforementioned method of manufacturing the flat cell ROM device, the same photolithography mask layer is used to manufacture the P-type region and the N-type region, so that the P-type region having a higher concentration than the P-well is formed at an interface between the N-type region and the P-well in the device. Therefore, the P-type doping concentration at an interface of a channel region formed by the N-type region and the P well is increased. Thus a barrier height of a p-n junction is increased, thereby reducing the leakage current of the source-drain of the device. Therefore the punch through phenomenon is alleviated, and the withstand voltage of the device is increased. In addition, the N-type region and the P-type region are manufactured by using the same photolithography mask layer, thus there is no need to add additional isolation mask to improve the characteristic of resistance to breakdown of the device, thereby saving a production cost.

### BRIEF DESCRIPTION OF THE DRAWINGS

In order to illustrate the technical solution of the invention or prior art more clearly, hereinafter, a brief introduction of accompanying drawings employed in the description of the embodiments or the prior art is provided. It is apparent that accompanying drawings described hereinafter merely are several embodiments of the invention. For one skilled in the art, other drawings can be obtained according to the accompanying drawings, without a creative work.

FIG. 1 is a flowchart of a method of manufacturing a flat cell ROM device according to an embodiment;

FIG. 2 is a schematic diagram of the device after performing step S130 of the method of manufacturing the flat cell ROM device of FIG. 1;

FIG. 3 is a schematic diagram of the device after performing step S140 of the method of manufacturing the flat cell ROM device of FIG. 1;

FIG. 4 is a schematic diagram of the device after performing step S150 of the method of manufacturing the flat cell ROM device of FIG. 1;

FIG. 5 is a graphic diagram illustrating a doping distribution of an interface between a channel region and a N-type region of the flat cell ROM device of FIG. 4; and

FIG. 6 is a graphic diagram illustrating a characteristic of current to voltage of the flat cell ROM device of FIG. 4.

### DETAILED DESCRIPTION OF THE EMBODIMENTS

Embodiments of the present disclosure are described more fully hereinafter with reference to the accompanying drawings, in which some embodiments of the present disclosure are shown. The various embodiments of the present disclosure may, however, be embodied in many different forms and should not be construed as limited to the embodiments set forth herein. Rather, these embodiments are provided so that this disclosure will be thorough and complete, and will fully convey the scope of the present disclosure to those skilled in the art.

In the specification and accompanying drawings, the reference signs N and P assigned to the layers or regions indicate that such layers or regions contains a large number of electrons or holes. Further, reference signs + and − assigned to the N or P indicate that a concentration of dopant is greater or lower than a concentration in the layers without such signs. In the following description and accompanying drawing of the embodiment, similar components aligned similar reference sings and redundant illustration is omitted herein.

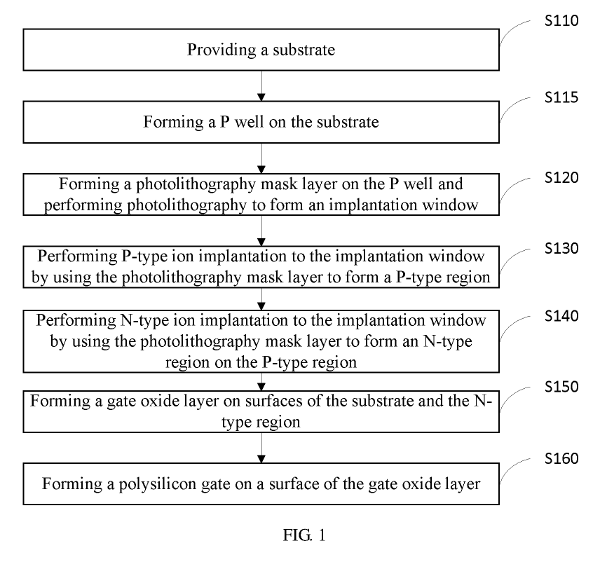

FIG. 1 is a flowchart of a method of manufacturing a flat cell ROM device according to an embodiment, the method of manufacturing the flat cell ROM device includes the following steps of :

In step S110, a substrate is provided.

The substrate can be made of silicon, carborundum, gallium arsenide, and indium phosphide. The resistivity of the substrate can be configured according to a demand of a withstand voltage of the device to be manufactured.

In step S115, a P well is formed on the substrate.

P-type ion implantation is performed on the substrate to form the P well.

In step S120, a photolithography mask layer is formed on the P well and photolithograph is performed to form an implantation window.

In step S130, the P-type ion implantation is performed to the implantation window by using the photolithography mask layer to form a P-type region.

The formed photolithography mask layer is used as a blocking layer to perform the P-type ion implantation to form the P-type region. In the illustrated embodiment, the P-type ion implantation is performed at a tilt angle, i.e., the P-type ion is implanted at a certain angle with respect to a vertical plane. The angle can be 20 to 30 degrees. An implantation depth and region can be controlled by performing the P-type implantation at the certain angle. In the process of the P-type ion implantation, if the P-type ion concentration is too high, avalanche breakdown of the p-n junction may occur, and the BV of the device will be reduced. Therefore, a suitable dose of the P-type ion implantation is required to be selected. Specifically, the implanted P-type ion is boron, and the dose of the implanted P-type ion is 7×10¹² cm⁻² to 3×10¹³ cm⁻². In an alternative embodiment, the P-type ion can be indium or boron difluoride (BF₂).

FIG. 2 is a schematic diagram of performing step S130. As shown in FIG. 2, the P well 202 is formed on the substrate (not shown), the photolithography mask layer 20 and the P-type region formed by performing the P-type ion implantation at a angle are formed on a surface of the P well. In the illustrated embodiment, the P-type region includes a first P-type region 204 and a second P-type region 206.

In step S140, N-type ion implantation is performed to the implantation window by using the photolithography mask layer, so as to form an N-type region on the P-type region.

Specifically, an N+ region is formed in the P-type region by the N-type ion implantation. In the illustrated embodiment, the N-type ion is arsenic, and the N-type ion implantation is performed perpendicular to the surface of the device. In an alternative embodiment, the N-type ion is phosphorus or antimony.

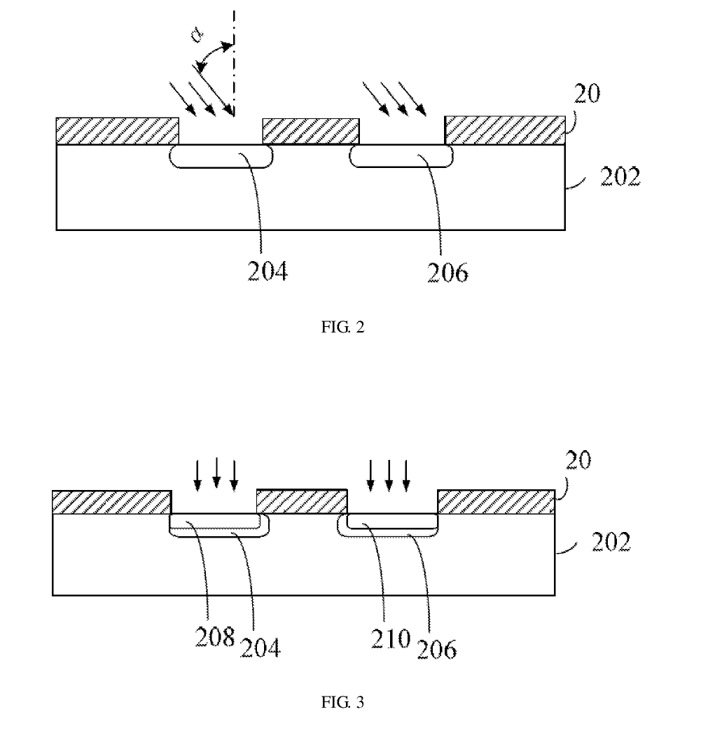

FIG. 3 is a schematic diagram after performing the step S140. As shown in FIG. 3, a first N+ region 208 and a second N+ region 210 are formed on the P-type region. The first N+ region 208 and the second N+ region 210 serve as a source and a drain of the flat cell ROM device, respectively. The P well 202 forms a channel region of the flat cell ROM device. The P-type region is located at an interface between the N-type region and the P-well 202, which increases the P-type doping concentration at an interface between the N-type region and the channel region and a barrier height of the p-n junction. Thus, electron needs to stride the barrier from one N-type region to the other N-type region, thereby reducing the leakage current of the source-drain of the device. Therefore the punch through phenomenon of the source-drain is alleviated, and the withstand voltage of the device is increased.

After completing the step of ion implantation, it is also necessary to perform the step of removing the photolithography mask layer and performing a corresponding thermal process. By merits of the proper thermal process via the furnace tube, the P-type impurity can diffuse to the interface of the channel region, therefore the doping concentration of the channel region is increased without affecting the size of the channel. For those skilled in the art, it is a common manufacturing process to accelerate the diffusion of the P-type doping by the thermal process, thus temperature and a length of the time during the thermal process can be selected by those skilled in the art according to the actual requirement.

S150: a gate oxide layer is formed on surfaces of the substrate and the N-type region.

S160: a polysilicon gate is formed on a surface of the gate oxide layer.

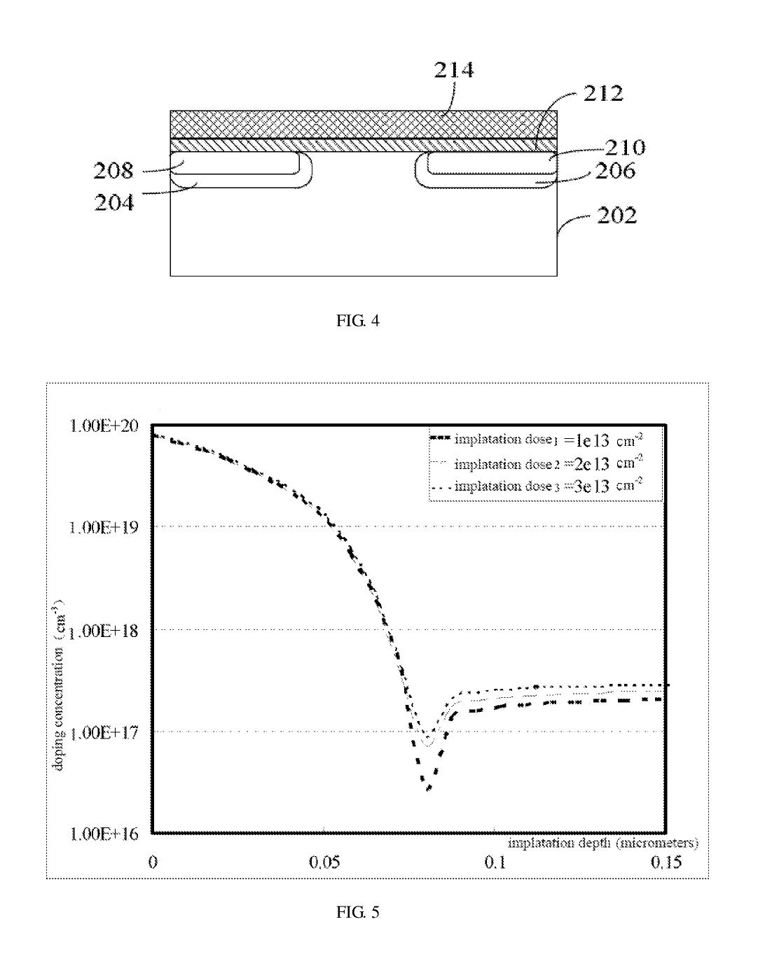

After performing the ion implantation, the gate oxide layer and the polysilicon gate are formed by steps S150 and S160, and the corresponding subsequent steps are performed to accomplish the manufacturing process of the device. FIG. 4 is a schematic diagram of the flat cell ROM device obtained according to the aforementioned manufacturing method. The gate oxide layer 212 is formed on the surface of the device, and the polysilicon gate 214 is formed on the surface of the gate oxide layer 212.

According to the aforementioned method of manufacturing the flat cell ROM device, the P-type ion implantation and the N-type ion implantation are performed using the same photolithography mask layer, so that the P-type region having a higher concentration than that of the P-well is formed at an interface between the N-type region and the P-well of the device. Therefore, the P-type doping concentration at an interface between the N-type region and a channel region is increased, a barrier height of a P-N junction is increased, thereby reducing the leakage current of the source-drain of the device. Therefore the punch through phenomenon is alleviated, and the withstand voltage of the device is improved. In addition, the N-type region and the P-type region are manufactured by using the same photolithography mask layer, thus there is no need to add additional isolation mask to improve the characteristic of resistance to breakdown of the device, thereby saving a production cost. The adjustment of the withstand voltage of the device can be achieved by controlling the implantation dose and angle of the implanted P-type ion. In the illustrated embodiment, the implantation dose of the implanted P-type ion is 7×10¹² cm⁻² to 3×10¹³ cm⁻², and the withstand voltage can be increased by 5V to 8V.

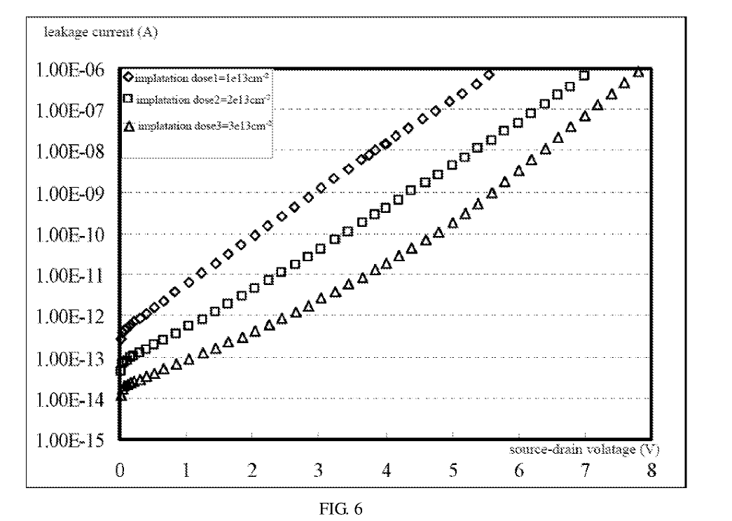

In the illustrated embodiment, by merit of controlling the dose of the ion implantation in the P-type region, the control of the doping concentration of the region can be achieved. Therefore the ability of the withstand voltage of the device and preventing the punch though can be adjusted. FIG. 5 is a graphic diagram illustrating a doping distribution of the interface between the channel region and the N-type region of the flat cell ROM device manufactured according to the aforementioned method. A abscissa indicates a implanted depth of the ion, in a unit of micrometers (μm), a ordinate indicates the doping concentration of the implanted ion in the implanted region. In the illustrated embodiment, a ion implantation surface represents the starting point “0” and the direction of the ion implantation is positive. For example, in the drawing, 0.05 μm indicates a depth which is 0.05 μm away from the ion implantation surface along a direction of the ion implantation. By increasing the implantation dose of P-type doping, the doping concentration in the channel region is increased, thus the withstand voltage of the device is increased. FIG. 6 is a graphic diagram illustrating a characteristic between electricity to voltage of the flat cell ROM device. A abscissa indicates a source-drain voltage V_{ds}, in a unit of volt (V), a ordinate indicates a drain current Id, in units of ampere (A). It can be seen from the drawing that under the same drain current Id, the larger the implanted ion dose is, the greater the source-drain voltage is, thus the device manufactured according to the method of the present disclosure has a great ability of preventing the punch through phenomenon.

Although the respective embodiments have been described one by one, it shall be appreciated that the respective embodiments will not be isolated. Those skilled in the art can apparently appreciate upon reading the disclosure of this application that the respective technical features involved in the respective embodiments can be combined arbitrarily between the respective embodiments as long as they have no collision with each other. Of course, the respective technical features mentioned in the same embodiment can also be combined arbitrarily as long as they have no collision with each other.

The aforementioned implementations are merely specific embodiments of the present disclosure, but are not intended to limit the protection scope of the present disclosure. It should be noted that persons skilled in the art can understand and embody all or part of flowcharts of the aforementioned implementations. Equivalent variation figured out by persons skilled in the art shall all fall within the protection scope of the present disclosure.

What is claimed is:

1. A method of manufacturing a flat cell read-only memory (ROM) device, comprising the following steps of:
providing a substrate;
forming a P well on the substrate;
forming a photolithography mask layer on the P well and performing photolithography to form an implantation window;
performing P-type ion implantation to the implantation window by using the photolithography mask layer to form a P-type region;
performing N-type ion implantation to the implantation window by using the photolithography mask layer to form an N-type region on the P-type region; wherein the N-type region comprises a first N-type region and a second N-type region; the first N-type region and the second N-type region serve as a source and a drain of the flat cell ROM device, respectively;
forming a gate oxide layer on surfaces of the substrate and the N-type region; and
forming a polysilicon gate on a surface of the gate oxide layer.

2. The method of claim 1, wherein in the step of performing the P-type ion implantation to the implantation window by using the photolithography mask layer to form the P-type region, the P-type ion implantation is performed at a tilt angle.

3. The method of claim 2, wherein the P-type ion is implanted at 20 to 30 degrees with respect to a vertical plane.

4. The method of claim 1, wherein in the step of performing the P-type ion implantation to the implantation window by using the photolithography mask layer to form the P-type region, a dose of the implanted P-type ion is 7×10¹² cm⁻² to 3×10¹³ cm⁻².

5. The method of claim 1, wherein after the step of performing the N-type ion implantation to the implantation window by using the photolithography mask layer to form the N-type region on the P-type region, the method further comprises the step of performing thermal process.

6. The method of claim 1, wherein the P-type ion is one of boron, indium and boron difluoride.

7. The method of claim 1, wherein the N-type ion is one of arsenic, phosphorus and antimony.

8. The method of claim 1, wherein the P-type ion is boron, and the N-type ion is arsenic.

9. The method of claim 1, wherein in the step of performing the N-type ion implantation to the implantation window by using the photolithography mask layer to form the N-type region on the P-type region, the N-type ion is implanted in a direction perpendicular to the surface of the substrate.

10. The method of claim 1, wherein the substrate is made of one of silicon, carborundum, gallium arsenide, and indium phosphide.
